(19) United States
(12) Patent Application Publication
(10) Pub. No.: US 2012/0211061 A1
(43) Pub. Date: Aug. 23, 2012

(54) ORGANIC PHOTOVOLTAIC CELL AND ORGANIC PHOTOVOLTAIC MODULE

(76) Inventors: Takehito Kato, Oyama-shi (JP); Toshihiro Ohnishi, Tsukuba-shi (JP)

(21) Appl. No.: 13/503,968

(22) PCT Filed: Oct. 26, 2010
(86) PCT No.: PCT/JP2010/068934

§ 371 Date: Apr. 25, 2012

(30) Foreign Application Priority Data
Oct. 30, 2009 (JP) 2009-250580

(51) Int. Cl. H01L 31/0232; H01L 31/048

(52) U.S. Cl. 136/251; 136/257

(57) ABSTRACT

Provided is an organic photovoltaic cell having a long lifetime. An organic photovoltaic cell 100 comprises a first electrode 2, a second electrode 4, an active layer 3 provided between the first electrode 2 and the second electrode 4 and capable of generating a charge by incident light, and a barrier layer that is configured to be a surface of the organic photovoltaic cell, and that includes an inorganic sealing layer 7 comprising an inorganic material, a resin layer 8 formed from a resin, and an ultraviolet absorbing layer 9 in this order from the active layer 3.

### TECHNICAL FIELD

The present invention relates to an organic photovoltaic cell and an organic photovoltaic module.

### BACKGROUND ART

A photovoltaic cell is a cell that can convert light energy into electric energy and an example thereof is a solar cell. The solar cell typically includes a silicon solar cell. However, the silicon solar cell requires a high vacuum environment and a high pressure environment in the production process to increase production cost. On this account, an organic solar cell has been drawing attention because the production cost of the organic solar cell is lower than that of the silicon solar cell.

However, the organic solar cell uses an organic material, which is likely to deteriorate due to oxygen, water, ultraviolet light (UV), and the like, and thus the organic solar cell tends to have shorter lifetime than that of the silicon solar cell. Hence, in order to elongate the lifetime of the organic solar cell, various techniques have been developed. For example, Patent Document 1 discloses an organic photovoltaic cell that comprises a surface protective layer in order to block oxygen and water.

### RELATED ART DOCUMENTS

### Patent Literature

Patent Document 1: JP No. 2004-165512 A

### SUMMARY

The organic photovoltaic cell that comprises the surface protective layer in order to block oxygen and water penetrating into the organic photovoltaic cell can suppress the deterioration of the organic material in the organic photovoltaic cell due to the oxygen and water to elongate the lifetime of the organic photovoltaic cell. However, the technique according to Patent Document 1 does not sufficiently elongate the lifetime; there is a demand for techniques that can further elongate the lifetime of the organic photovoltaic cell.

In view of the above problems, the present invention provides an organic photovoltaic cell and an organic photovoltaic module having a long lifetime.

The inventors of the present invention have carried out intensive studies in order to solve the problems; as a result, they have found that, by providing a barrier layer that comprises an inorganic sealing layer comprising an inorganic material, a resin layer formed from a resin, and an ultraviolet absorbing layer capable of absorbing ultraviolet light, the organic photovoltaic cell can be protected from oxygen and water as well as ultraviolet light and the organic photovoltaic cell can also be protected from external force by taking advantages of the resin. In this manner, the present invention has been accomplished.

That is, the present invention is as follows.

[1] An organic photovoltaic cell comprising:

a first electrode;

a second electrode; and

an active layer provided between the first electrode and the second electrode and capable of generating a charge by incident light, and

a barrier layer that is configured to be a surface of the organic photovoltaic cell, and that comprises an inorganic sealing layer comprising an inorganic material, a resin layer formed from a resin, and an ultraviolet absorbing layer in this order from the active layer.

[2] The organic photovoltaic cell according to [1], wherein the ultraviolet absorbing layer has one or both of a function of blocking absorbed ultraviolet light and a function of wavelength conversion of absorbed ultraviolet light into light having longer wavelength than that of the ultraviolet light.
[3] An organic photovoltaic module comprising:

a cell group comprising two or more organic photovoltaic cells that each comprises a first electrode, a second electrode, and an active layer provided between the first electrode and the second electrode and capable of generating a charge by incident light, and the two or more organic photovoltaic cells being electrically connected to each other; and

a barrier layer covering the cell group, wherein

the barrier layer comprises an inorganic sealing layer comprising an inorganic material, a resin layer formed from a resin, and an ultraviolet absorbing layer in this order from the organic photovoltaic cells.

[4] The organic photovoltaic cell according to [1] or [2], wherein the inorganic sealing layer, the resin layer, and the ultraviolet absorbing layer are formed through a coating process.

### BRIEF DESCRIPTION OF DRAWINGS

FIG. 1 is a schematic cross-sectional view of an organic photovoltaic cell of an embodiment of the present invention.

FIG. 2 is a schematic cross-sectional view of an organic photovoltaic module of an embodiment of the present invention.

### EXPLANATIONS OF LETTERS OR NUMERALS

1 substrate
2 first electrode
3 active layer
4 second electrode
5 substrate
6 barrier layer
7 inorganic sealing layer
8 resin layer
9 ultraviolet absorbing layer
10 supporting substrate
11 first electrode
12 active layer
13 second electrode
14 organic photovoltaic cell
15 cell group
16 barrier layer
17 inorganic sealing layer
18 resin layer
19 ultraviolet absorbing layer
100 organic photovoltaic cell
200 organic photovoltaic module

### DESCRIPTION OF EMBODIMENTS

Hereinafter, the present invention will be described in detail with reference to embodiments, exemplary substances, and the like, but the present invention is not limited thereto, and any changes and modifications may be made in the present invention without departing from the gist of the present invention. In the present invention, “ultraviolet light” refers to light having a wavelength of 400 nm or less.

### 1. Outline

The organic photovoltaic cell of the present invention comprises a first electrode, a second electrode, an active layer that is provided between the first electrode and the second electrode and that can generate a charge by incident light, and a barrier layer that is configured to be a surface of the organic photovoltaic cell. The barrier layer comprises an inorganic sealing layer comprising an inorganic material, a resin layer formed from a resin, and an ultraviolet absorbing layer capable of absorbing ultraviolet light in this order from the active layer.

The inorganic sealing layer can generally block oxygen and water that penetrate from outside to inside of the organic photovoltaic cell. The resin layer can generally further increase the oxygen and water blocking performance. The resin layer can generally suppress damage to the inorganic sealing layer caused by external force from outside of the organic photovoltaic cell to the inorganic sealing layer. The ultraviolet absorbing layer can generally suppress deterioration of organic materials comprised in the resin layer, the active layer and the functional layer due to ultraviolet light. Therefore, the organic photovoltaic cell of the present invention that comprises the inorganic sealing layer, the resin layer, and the ultraviolet absorbing layer in combination can be effectively protected from oxygen, water, ultraviolet light, and external force; therefore, the organic photovoltaic cell can stably maintain photovoltaic conversion characteristics for a long time to elongate the lifetime.

The organic photovoltaic cell of the present invention may further have other layers in addition to the first electrode, the active layer, the second electrode, and the barrier layer. For example, the organic photovoltaic cell of the present invention may have a functional layer between the first electrode and the active layer, and may have a functional layer between the active layer and the second electrode.

The organic photovoltaic cell of the present invention usually further comprises a substrate and, on the substrate, each layer (for example, the first electrode, the active layer, the second electrode, and the functional layers) is stacked to constitute the organic photovoltaic cell of the present invention.

### 2. Substrate

The substrate is a member serving as a support of the organic photovoltaic cell of the present invention. The substrate usually employs a member that is not chemically changed during the formation of the electrode and the formation of an organic material layer. Examples of a material for the substrate may include glass, a plastic, a polymer film, and silicon. The materials for the substrate may be used alone or in combination of two or more of them at any ratio.

Usually, a transparent or translucent member is used as the substrate, but an opaque substrate may be used. However, when the opaque substrate is used, the electrode opposite to the opaque substrate (namely, either the first electrode or the second electrode which is the electrode more distant from the opaque substrate) is preferably transparent or translucent.

### 3. First Electrode and Second Electrode

Of the first electrode and the second electrode, one is an anode and the other is a cathode. At least one of the first electrode and the second electrode is preferably transparent or translucent so that light can readily enter the active layer placed between the first electrode and the second electrode. The organic photovoltaic cell of the present invention can reduce the intensity of ultraviolet light included in light that passes through the barrier layer and enters the active layer. Thus, the first electrode is preferably transparent or translucent when the barrier layer is configured to be a surface closer to the first electrode than the active layer, while the second electrode is preferably transparent or translucent when the barrier layer is configured to be a surface closer to the second electrode than the active layer.

Examples of the transparent or translucent electrode may include an electrically conductive metal oxide film and a translucent metal thin film. Examples of a material for the transparent or translucent electrode may include: films formed using electrically conductive materials such as indium oxide, zinc oxide, tin oxide, complexes of them such as indium tin oxide (ITO), indium zinc oxide (IZO), and NESA; gold; platinum; silver; and copper. Among them, ITO, indium zinc oxide, and tin oxide are preferred.

As the material for the transparent or translucent electrode, an organic material may also be used. Examples of the organic material usable as the material for the electrode may include electrically conductive polymers such as polyaniline, a derivative thereof, polythiophene, and a derivative thereof.

Examples of a material for the opaque electrode may include a metal and an electrically conductive polymer. Specific examples of the material may include: metals such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of the metals; an alloy of one or more of the metals and one or more of metals selected from a group consisting of gold, silver, platinum, copper, manganese, titanium, cobalt, nickel, tungsten, and tin; graphite; a graphite intercalation compound; polyaniline and a derivative thereof; and polythiophene and a derivative thereof. Specific examples of the alloy may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The materials for the electrode may be used alone or in combination of two or more of them at any ratio.

Each of the first electrode and the second electrode has a varied thickness depending on the material type of the electrode. The thickness is preferably 500 nm or smaller and more preferably 200 nm or smaller in order to increase transmittance of light and to suppress electric resistance. The thickness has no lower limit but is usually 10 nm or larger.

Examples of the formation method of the first electrode and the second electrode may include a vacuum deposition method, a sputtering method, an ion plating method, and a plating method. For the formation of the first electrode and the second electrode from, for example, an electrically conductive polymer, a coating method may be employed.

### 4. Active Layer

The active layer is a layer capable of generating a charge by incident light and usually comprises a p-type semiconductor that is an electron-donor compound and an n-type semiconductor that is an electron-acceptor compound. The organic photovoltaic cell of the present invention uses organic compounds as at least one of the p-type semiconductor and the n-type semiconductor, usually as both semiconductors, and hence is called the “organic” photovoltaic cell. The p-type semiconductor and the n-type semiconductor are relatively determined by the energy level of each energy state of the semiconductors.

In the active layer, the charge is supposed to be generated in the following manner. When light energy input to the active layer is absorbed in one or both of the n-type semiconductor and the p-type semiconductor, an exciton comprising an electron and a hole bonded to each other is formed. The formed exciton is transferred to reach to a heterojunction interface where the n-type semiconductor is in contact with the p-type semiconductor. Then, the electron and hole are separated due to corresponding differences of the HOMO (highest occupied molecular orbital) energies and the LUMO (lowest unoccupied molecular orbital) energies at the heterojunction interface, thus generating charges (electron and hole) that can independently move. The generated charges are transferred to the corresponding electrodes to be able to be extracted from the organic photovoltaic cell of the present invention as electric energy (current) to the exterior.

The active layer may have a single layer structure comprising one layer alone or may have a stacked structure comprising two or more layers as long as the layer can generate a charge by incident light. Examples of the layer composition of the active layer may include the following layer compositions. However, the layer composition of the active layer is not limited to the examples.

Layer composition (i): the active layer having a stacked structure comprising a layer comprising the p-type semiconductor and a layer comprising the n-type semiconductor.

Layer composition (ii): the active layer having a single layer structure comprising the p-type semiconductor and the n-type semiconductor.

Layer composition (iii): the active layer having a stacked structure comprising a layer comprising the p-type semiconductor, a layer comprising the p-type semiconductor and the n-type semiconductor, and a layer comprising the n-type semiconductor.

Examples of the p-type semiconductor may include a pyrazoline derivative, an arylamine derivative, a stilbene derivative, a triphenyldiamine derivative, oligothiophene and a derivative thereof, polyvinylcarbazole and a derivative thereof, polysilane and a derivative thereof, a polysiloxane derivative having an aromatic amine on a side chain or the main chain, polyaniline and a derivative thereof, polythiophene and a derivative thereof, polypyrrole and a derivative thereof, poly(phenylene vinylene) and a derivative thereof, and poly(thienylene vinylene) and a derivative thereof.

An organic macromolecular compound having a structural unit represented by the following structural formula (1) is preferred as the p-type semiconductor.

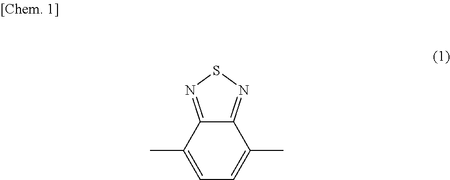

The organic macromolecular compound is more preferably a copolymer of the compound having the structural unit represented by the structural formula (1) and a compound represented by the following structural formula (2).

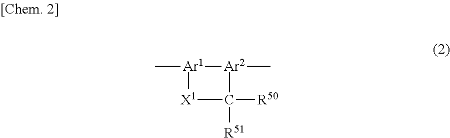

[In Formula (2), Ar¹ and Ar² are the same as or different from each other and represent a trivalent heterocyclic group. X¹ represents —O—, —S—, —C(═O)—, —S(═O)—, —SO₂—, —Si(R³)(R⁴)—, —N(R⁵)—, —B(R⁶)—, —P(R⁷)—, or —P(═O) (R⁸)—. R³, R⁴, R⁵, R⁶, R⁷, and R⁸ are the same as or different from each other and represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having six or more carbon atoms, an alkyloxy group having six or more carbon atoms, an alkylthio group having six or more carbon atoms, an aryl group having six or more carbon atoms, an aryloxy group having six or more carbon atoms, an arylthio group having six or more carbon atoms, an arylalkyl group having seven or more carbon atoms, an arylalkyloxy group having seven or more carbon atoms, an arylalkylthio group having seven or more carbon atoms, an acyl group having six or more carbon atoms, or an acyloxy group having six or more carbon atoms. X¹ and Ar² are bonded to vicinal positions of the heterocyclic ring comprised in Ar¹, and C(R⁵⁰)(R⁵¹) and Ar¹ are bonded to vicinal positions of the heterocyclic ring comprised in Ar²]

The p-type semiconductors may be used alone or in combination of two or more of them at any ratio.

Examples of the n-type semiconductor may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, metal complexes of 8-hydroxyquinoline and a derivative thereof, polyquinoline and a derivative thereof, polyquinoxaline and a derivative thereof, polyfluorene and a derivative thereof, fullerenes such as C₆₀ and a derivative thereof, a phenanthrene derivative such as bathocuproine, a metal oxide such as titanium dioxide, and a carbon nanotube. Among them, titanium dioxide, a carbon nanotube, a fullerene, and a fullerene derivative are preferred, and a fullerene and a fullerene derivative are especially preferred.

Examples of the fullerene may include C₆₀ fullerene, C₇₀ fullerene, C₇₆ fullerene, C₇₈ fullerene, and C₈₄ fullerene.

Examples of the fullerene derivative may include derivatives of C₆₀, C₇₀, C₇₆, C₇₈, and C₈₄. Specific examples of the fullerene derivative may include compounds having the following structures.

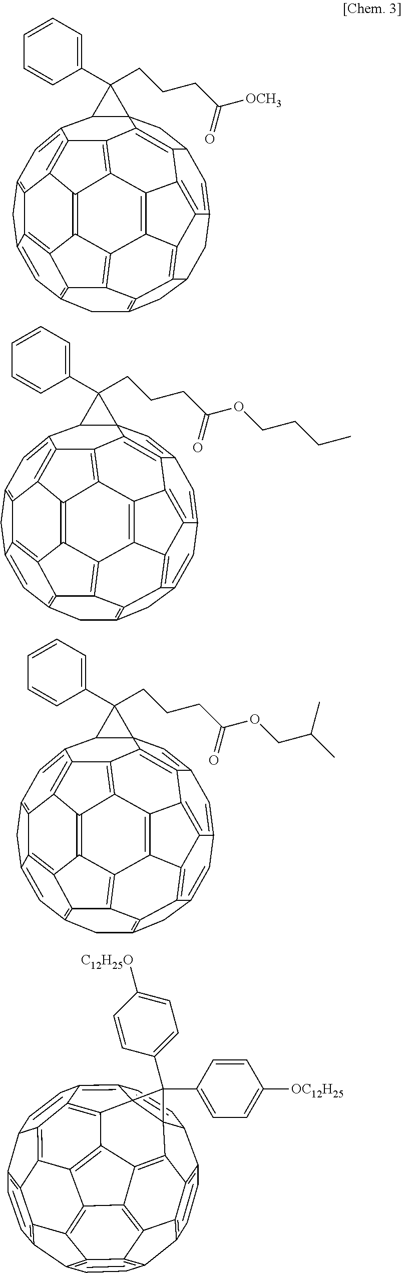

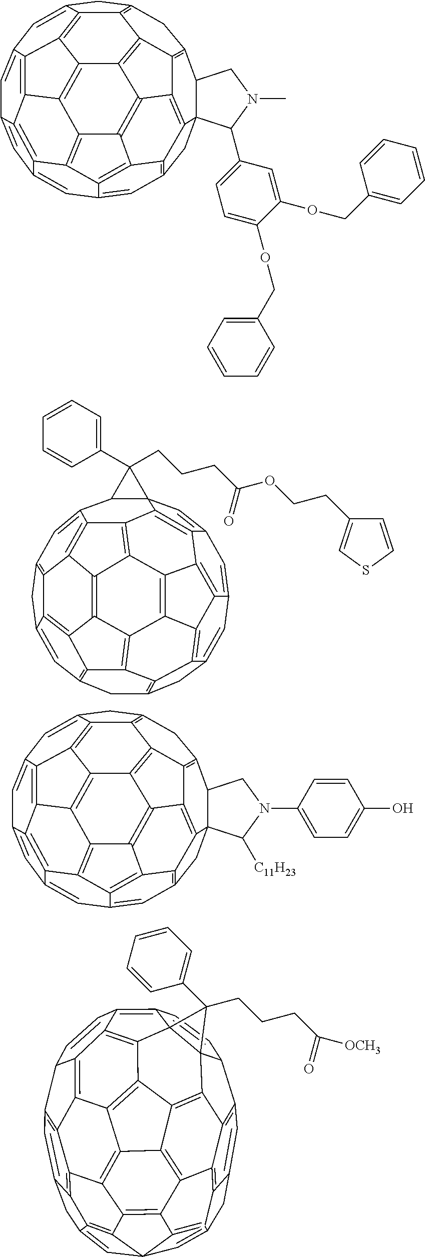

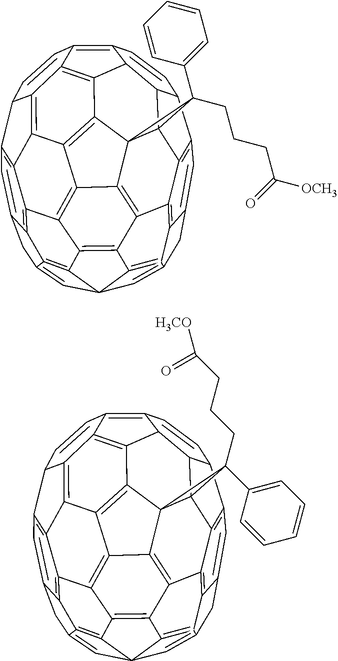

Other examples of the fullerene derivative may include [6,6]-phenyl C₆₁ butyric acid methyl ester (C60PCBM), [6,6]-phenyl C₇₁ butyric acid methyl ester (C70PCBM), [6,6]-phenyl C₈₅ butyric acid methyl ester (C84PCBM), and [6,6]-thienyl C₆₁ butyric acid methyl ester.

The n-type semiconductors may be used alone or in combination of two or more of them at any ratio.

The active layer may comprise the p-type semiconductor and the n-type semiconductor at any ratio as long as the effect of the present invention is not impaired. For example, in a layer comprising both of the p-type semiconductor and the n-type semiconductor in the layer compositions (i) and (iii), the n-type semiconductor is preferably comprised in an amount of 10 parts by weight or more and more preferably 20 parts by weight or more, and is preferably comprised in an amount of 1,000 parts by weight or less and more preferably 500 parts by weight or less, with respect to 100 parts by weight of the p-type semiconductor.

The active layer usually has a thickness of 1 nm or larger, preferably 2 nm or larger, more preferably 5 nm or larger, and particularly preferably 20 nm or larger, and usually has a thickness of 100 μm or smaller, preferably 1,000 nm or smaller, more preferably 500 nm or smaller, and particularly preferably 200 nm or smaller.

The active layer may be formed by any method. Examples of the method may include a film formation method from a liquid composition comprising a material (for example, one or both of the p-type semiconductor and the n-type semiconductor) for the active layer; and a film formation method by a gas phase film formation method such as a physical vapor deposition method (PVD method) including a vacuum deposition method and a chemical vapor deposition method (CVD method). Among them, the film formation method from a liquid composition is preferred because a film is readily formed to reduce the cost.

In the film formation method from a liquid composition, a liquid composition is prepared, the liquid composition is applied onto a desired area to form a film as the active layer.

The liquid composition usually comprises a material for the active layer and a solvent. When the solvent is contained, the liquid composition may be a dispersion liquid dispersing the material for the active layer in the solvent, but is preferably a solution dissolving the material for the active layer in the solvent. Hence, the solvent to be used is preferably a solvent that can dissolve the material for the active layer. Examples of the solvent may include: unsaturated hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran and tetrahydropyran. The solvents may be used alone or in combination of two or more of them at any ratio.

Each concentration of the p-type semiconductor and the n-type semiconductor in the liquid composition is usually adjusted to 0.1% by weight or more with respect to a solvent.

Examples of the film formation method of the liquid composition may include coating methods such as a spin coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet printing method, a dispenser printing method, a nozzle coating method, and a capillary coating method. Among them, a spin coating method, a flexographic printing method, a gravure printing method, an inkjet printing method, and a dispenser printing method are preferred.

After the film formation of the liquid composition, as necessary, a process such as a process of drying the formed film to remove the solvent is performed, and consequently the active layer is obtained.

For an active layer having a stacked structure comprising two or more layers, for example, each layer constituting the active layer may be sequentially stacked by the aforementioned method.

### 5. Functional Layer

The organic photovoltaic cell of the present invention may comprise functional layers between the first electrode and the active layer and between the second electrode and the active layer. The functional layer is a layer that can transport the charge generated in the active layer to the electrode. The functional layer between the first electrode and the active layer can transport the charge generated in the active layer to the first electrode, while the functional layer between the second electrode and the active layer can transport the charge generated in the active layer to the second electrode. The functional layer may be provided either between the first electrode and the active layer or between the second electrode and the active layer, and the functional layers may be provided both between the first electrode and the active layer and between the second electrode and the active layer.

The functional layer provided between the active layer and an anode can transport a hole generated in the active layer to the anode, and is also called a hole transport layer or an electron block layer. Meanwhile, the functional layer provided between the active layer and a cathode can transport an electron generated in the active layer to the cathode, and is also called an electron transport layer or a hole block layer. The effective photovoltaic cell of the present invention that comprises the functional layers can increase extraction efficiency of the hole generated in the active layer to the anode, can increase extraction efficiency of the electron generated in the active layer to the cathode, can suppress transfer of the hole generated in the active layer to the cathode, and can suppress transfer of the electron generated in the active layer to the anode. Consequently, the photovoltaic conversion efficiency can be improved.

The functional layer may comprise a material that can transport the charge generated in the active layer. Specifically, the functional layer between the active layer and the anode preferable comprises a material that can transport the hole and that can suppress the transfer of the electron to the functional layer. The functional layer between the active layer and the cathode preferably comprises a material that can transport the electron and that can suppress the transfer of the hole to the functional layer.

Examples of the material for the functional layer may include: halides and oxides of an alkali metal or an alkaline earth metal, such as lithium fluoride; inorganic semiconductors such as titanium dioxide; bathocuproine, bathophenanthroline and a derivative thereof; a triazole compound; a tris(8-hydroxyquinolinate) aluminum complex; a bis(4-methyl-8-quinolinate) aluminum complex; an oxadiazole compound; a distyrylarylene derivative; a silole compound; a 2,2′,2″-(1,3,5-benzenetolyl)-tris-[1-phenyl-1H-benzimidazole] (TPBI) phthalocyanine derivative; a naphthalocyanine derivative; a porphyrin derivative; aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD); oxazole; oxadiazole; triazole; imidazole; imidazolone; a stilbene derivative; a pyrazoline derivative; tetrahydroimidazole; polyarylalkane; butadiene; 4,4′,4″-tris(N-(3-methylphenyl)-N-phenylamino)triphenylamine (m-MTDATA); polyvinylcarbazole; polysilane; and poly(3,4-ethylenedioxidethiophene) (PEDOT). The materials may be used alone or in combination of two or more of them at any ratio.

The functional layer may contain other components in addition to the aforementioned materials as long as the effect of the present invention is not significantly impaired.

The other components may be used alone or in combination of two or more of them at any ratio.

The functional layer usually has a thickness of 0.01 nm or larger, preferably 0.1 nm or larger, and more preferably 1 nm or larger, and usually has a thickness of 1,000 nm or smaller, preferably 500 nm or smaller, and more preferably 100 nm or smaller. The functional layer having an excessively small thickness may insufficiently exert the functions of the functional layer, while the functional layer having an excessively large thickness may excessively increase the thickness of the organic photovoltaic cell.

The functional layer may be formed, for example, by a gas phase film formation method, but is preferably formed through a process of applying a liquid composition comprising the material for the functional layer onto a predetermined area because the layer is readily formed to reduce the cost. The method for forming the functional layer from the liquid composition will be described below.

The liquid composition for forming the functional layer usually comprises a material for the functional layer and a solvent. When the solvent is contained, the liquid composition may be a dispersion liquid dispersing the material for the functional layer in the solvent and may be a solution dissolving the material for the functional layer in the solvent.

Examples of the solvent contained in the liquid composition for forming the functional layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the material for the functional layer.

After the preparation of the liquid composition for forming the functional layer, the liquid composition is applied onto a predetermined area where the functional layer is intended to be formed. Usually, the liquid composition is applied onto a layer (usually, the first electrode, the second electrode, or the active layer) to be in contact with the functional layer in the organic photovoltaic cell of the present invention. Examples of the coating method of the liquid composition may include coating methods similar to the coating methods of the liquid composition for forming the active layer.

The liquid composition for forming the functional layer is applied to form a film comprising the material for the functional layer. Thus, after the application of the liquid composition, as necessary, a process such as a process of drying the formed film to remove the solvent is performed, and consequently the functional layer is obtained.

### 6. Barrier Layer

The barrier layer is a layer that is configured to be a surface of the organic photovoltaic cell of the present invention and that comprises an inorganic sealing layer, a resin layer, and an ultraviolet absorbing layer in this order from the active layer. The barrier layer may be configured to be at least a part of the surface of the organic photovoltaic cell of the present invention and may be configured to be the whole surface of the organic photovoltaic cell of the present invention. Usually, the barrier layer is configured to be the surface area where the substrate is not provided in the organic photovoltaic cell of the present invention. Therefore, for example, when an organic photovoltaic cell including the substrate, the first electrode, the active layer, and the second electrode in this order includes the barrier layer, the organic photovoltaic cell usually has a layer structure comprising the first electrode, the active layer, the second electrode, and the barrier layer in this order from the substrate.

[6-1. Inorganic Sealing Layer]

The inorganic sealing layer is a layer that comprises an inorganic material and is a layer that is provided on the inside of the resin layer (the place close to the active layer) in the barrier layer. The inorganic material tends to have excellent anti-moisture permeability and anti-oxygen permeability in comparison with an organic material. Hence, the organic photovoltaic cell having a surface covered with the inorganic sealing layer comprising an inorganic material generally blocks the penetration of oxygen and water into the organic photovoltaic cell of the present invention, and thus being able to suppress the effect of oxygen and water from the outside on the organic photovoltaic cell.

The inorganic sealing layer preferably comprises an inorganic material that has high anti-moisture permeability and high anti-oxygen permeability and that is stable with respect to water such as water vapor. Examples of the inorganic material may include silicon compounds such as silicon oxide, silicon nitride, silicon oxynitride, and silicon carbide; aluminum compounds such as aluminum oxide, aluminium nitride, and aluminum silicate; metal oxides such as zirconium oxide, tantalum oxide, and titanium oxide; metal nitrides such as titanium nitride; and diamond-like carbon. Among them, silicon compounds such as silicon nitride, silicon oxide, silicon oxynitride, and silicon carbide; aluminum compounds such as aluminum oxide, aluminium nitride, and aluminum silicate; zirconium oxide; tantalum oxide; titanium oxide; and titanium nitride are preferred.

The inorganic materials may be used alone or in combination of two or more of them at any ratio.

The inorganic sealing layer may include other components in addition to the inorganic material as long as the effect of the present invention is not significantly impaired. Examples of the other components may include: a binder such as a resin; a getter agent (oxygen adsorbent and water adsorbent) such as an alkoxide; a surfactant; a dispersant; an ultraviolet absorber; and an antioxidant. The other components may be used alone or in combination of two or more of them at any ratio.

In the inorganic sealing layer, the inorganic material is usually comprised at a ratio of 25% by weight or more and 100% by weight or less, preferably 50% by weight or more and 100% by weight or less, and more preferably 75% by weight or more and 100% by weight or less in order to stably exert the function of the inorganic sealing layer.

The inorganic sealing layer preferably has a thickness of 1 μm or larger, more preferably 3 μm or larger, and specifically preferably 5 μm or larger. The inorganic sealing layer having such a thickness can increase sealing properties of the organic photovoltaic cell and can stably block oxygen and water. For the inorganic sealing layer, the thickness has no upper limit, but is usually 10 μm or smaller from the viewpoints of the productivity, the cost, and the like.

Examples of the method for forming the inorganic sealing layer may include a gas phase film formation method such as a physical vapor deposition method (PVD method) and a chemical vapor deposition method (CVD method) (see “Thin Film Handbook” edited by Japan Society for the Promotion of Science, 131st Committee (Thin Film), (Ohmsha, Ltd.)). The gas phase film formation method is a deposition method at a molecular level. Hence, the method can form an inorganic sealing layer achieving excellent adhesion to an adjacent layer and can form a high quality inorganic sealing layer that can stably block the penetration of oxygen and water from an interface.

The inorganic sealing layer may also be formed, for example, by a coating method. The coating method is an economically advantageous method because a layer can be readily formed to reduce the cost. When the inorganic sealing layer is formed by the coating method, a liquid composition containing the inorganic material is firstly prepared, and a coating process of applying the prepared liquid composition onto a predetermined area is carried out to form the inorganic sealing layer.

The liquid composition for forming the inorganic sealing layer usually comprises a material for the inorganic sealing layer, such as the inorganic material and other components contained as necessary, and a solvent. When the solvent is comprised, the liquid composition may be a dispersion liquid dispersing the materials for the inorganic sealing layer in the solvent and may be a solution dissolving the materials for the inorganic sealing layer in the solvent.

Examples of the solvent contained in the liquid composition for forming the inorganic sealing layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more and is usually contained in an amount of 100,000 parts by weight or less, preferably 10,000 parts by weight or less, and more preferably 5,000 parts by weight or less, with respect to 100 parts by weight of the inorganic material.

After the preparation of the liquid composition for forming the inorganic sealing layer, the liquid composition is applied onto a predetermined area where the inorganic sealing layer is intended to be formed. Usually, the liquid composition is applied so as to cover a surface of the organic photovoltaic cell. Examples of the coating method of the liquid composition may include coating methods similar to the coating methods of the liquid composition for forming the active layer.

The liquid composition for forming the inorganic sealing layer is applied to form a film comprising the inorganic material. Thus, after the application of the liquid composition, as necessary, a process such as a process of drying the formed film to remove the solvent is performed, and consequently the inorganic sealing layer is obtained.

[6-2. Resin Layer]

The resin layer is a layer that is formed from a resin and is a layer that is provided between the inorganic sealing layer and the ultraviolet absorbing layer in the barrier layer. The resin has excellent flexibility comparing with the inorganic material. Thus, the covering on an outside of the inorganic sealing layer with the resin layer can generally suppress damage to the inorganic sealing layer caused by external force from outside of the organic photovoltaic cell to the inorganic sealing layer.

The arrangement of the resin layer can further increase the oxygen and water blocking performance in comparison with the arrangement of the inorganic sealing layer alone. Usually, the inorganic material has poor flexibility and thus is likely to cause defects and the like during the formation of the inorganic sealing layer. Hence, oxygen and water may readily penetrate from the defects and the like. Thus, in the organic photovoltaic cell of the present invention, the resin layer is provided for covering the defects and the like of the inorganic sealing layer with the resin to increase the oxygen and water blocking performance.

As the resin, various resins such as a thermosetting resin, a thermoplastic resin, and a photocurable resin may be used, and among them, the photocurable resin is preferred. This is because the organic photovoltaic cell does not deteriorate due to heat during the formation of the resin layer. Preferred examples of the resin may include a silicone resin, an epoxy resin, a fluorine resin, and a wax. The resins may be used alone or in combination of two or more of them at any ratio.

The resin layer preferably has a thickness of 1 μm or larger and more preferably 5 μm or larger. Such a resin layer can sufficiently cover defects and the like of the inorganic sealing layer to stably exert the function of blocking oxygen and water. The upper limit of the thickness of the resin layer is generally 100 μm or smaller and preferably 10 μm or smaller. The resin layer having an excessively large thickness may be likely to cause defects such as pinholes, voids, and cracks in the resin layer and may cause cracks in the barrier layer (especially, in the ultraviolet absorbing layer and the like) by thermal expansion of the resin layer when the organic photovoltaic cell is heated.

Examples of the method for forming the resin layer may include a gas phase film formation method, a coating method, and a method of bonding a previously formed film substance. Among them, the resin layer is preferably formed by the coating method because the layer can be readily formed to reduce the cost.

When the resin layer is formed by the coating method, a fluid resin is firstly prepared, and a coating process of applying the prepared resin onto a predetermined area is carried out to form the resin layer. The resin may contain a component that is not eventually contained in the resin layer, such as a solvent for controlling viscosity.

After the preparation of the fluid resin, the resin is applied. Usually, the resin is applied so as to cover a surface of the inorganic sealing layer. Examples of the coating method of the resin may include coating methods similar to the coating methods of the liquid composition for forming the active layer.

The resin is applied to form a film of the resin, and, as necessary, the solvent is dried or the resin is cured by light or heat to form the resin layer.

[6-3. Ultraviolet Absorbing Layer]

The ultraviolet absorbing layer is a layer that can absorb incident ultraviolet light and is a layer that is provided on the outside of the resin layer (the place far from the active layer) in the barrier layer. The ultraviolet absorbing layer absorbs ultraviolet light included in light that is applied to the organic photovoltaic cell of the present invention to be able to suppress the deterioration of organic materials comprised in the resin layer, the active layer, the functional layer, and the like due to ultraviolet light as much as at least the absorbed ultraviolet light.

The ultraviolet absorbing layer preferably has one or both of a function of blocking absorbed ultraviolet light and a function of wavelength conversion of absorbed ultraviolet light into light having longer wavelength than that of the ultraviolet light.

The ultraviolet absorbing layer that has the function of blocking absorbed ultraviolet light can suppress the deterioration of the organic materials comprised in the resin layer, the active layer, the functional layer, and the like due to ultraviolet light as much as the blocked ultraviolet light as described above.

Meanwhile, when the ultraviolet absorbing layer has the function of wavelength conversion of absorbed ultraviolet light into light having longer wavelength than that of the ultraviolet light, at least some of ultraviolet light that is input to the ultraviolet absorbing layer is subjected to wavelength conversion into light having longer wavelength than that of the input ultraviolet light; the resulting light is output from the ultraviolet absorbing layer to the exterior. At least some of the light that is output from the ultraviolet absorbing layer and that has longer wavelength than that of the ultraviolet light is input to the active layer and is used as light energy for charge generation in the active layer. Therefore, when the ultraviolet absorbing layer has the function of wavelength conversion of absorbed ultraviolet light into light having longer wavelength than that of the ultraviolet light, the organic photovoltaic cell of the present invention can reduce passing ultraviolet light to suppress the deterioration of the organic materials as well as can increase the charge generation amount in the active layer to improve photovoltaic conversion efficiency.

The output light that has been subjected to wavelength conversion from the absorbed ultraviolet light may be visible light, near infrared light, or infrared light, for example. The visible light is preferred in order to increase the photovoltaic conversion efficiency.

In order to achieve the aforementioned functions, the ultraviolet absorbing layer usually comprises an ultraviolet absorber that is a material capable of absorbing ultraviolet light. As the ultraviolet absorber, an organic material may be used and an inorganic material may be used.

Among the ultraviolet absorbers capable of absorbing and blocking ultraviolet light, examples of the organic material may include: benzophenone ultraviolet absorbers, benzotriazole ultraviolet absorbers, triazine ultraviolet absorbers, and phenyl salicylate ultraviolet absorbers. Among them, preferred examples specifically may include 2,4-dihydroxy-benzophenone, 2-hydroxy-4-methoxybenzophenone, 4-dodecyloxy-2-hydroxybenzophenone, 2-hydroxy-4-methoxy-5-sulfobenzophenone, 2-(2′-hydroxy-5-methylphenyl)benzotriazole, 2-(2′-hydroxy-3′,5′-di-tert-butylphenyl)benzotriazole, phenyl salicylate, p-octylphenyl salicylate, and p-tert-butylphenyl salicylate. Examples of the ultraviolet absorber composed of the inorganic material capable of absorbing and blocking ultraviolet light may include titanium dioxide and zinc oxide.

Examples of the ultraviolet absorber that can absorb ultraviolet light and perform wavelength conversion of the ultraviolet light into light having longer wavelength than that of the ultraviolet light may include a phosphor. The phosphor is usually a material that can absorb excitation light to emit fluorescence having longer wavelength than that of the excitation light. Hence, for the phosphor used as the ultraviolet absorber that can absorb ultraviolet light and perform wavelength conversion of the ultraviolet light into light having longer wavelength than that of the ultraviolet light, a phosphor capable of absorbing ultraviolet light as the excitation light and capable of emitting fluorescence having such wavelength available for the charge generation in the active layer may be used.

Among the phosphors, examples of the organic phosphor may include a rare earth complex. The rare earth complex is a phosphor excellent in fluorescent characteristics, and specific examples may include a [Tb(bpy)₂]Cl₃ complex, an [Eu(phen)₂]Cl₃ complex, and a [Tb(terpy)₂]Cl₃ complex. Here, “bpy” represents 2,2-bipyridine, “phen” represents 1,10-phenanthroline, and “terpy” represents 2,2′:6′,2″-terpyridine. Examples of the inorganic phosphor may include MgF₂:Eu²⁺ (an absorption wavelength of 300 nm to 400 nm, a fluorescence wavelength of 400 nm to 550 nm), 1.29(Ba, Ca)O-6Al₂O₃:Eu²⁺ (an absorption wavelength of 200 nm to 400 nm, a fluorescence wavelength of 400 nm to 600 nm), BaAl₂O₄:Eu²⁺ (an absorption wavelength of 200 nm to 400 nm, a fluorescence wavelength of 400 nm to 600 nm), and Y₃Al₅O₁₂:Ce³⁺ (an absorption wavelength of 250 nm to 450 nm, a fluorescence wavelength of 500 nm to 700 nm). Among the phosphors, the inorganic phosphors are preferably used.

The ultraviolet absorbers may be used alone or in combination of two or more of them at any ratio. As the ultraviolet absorber, an ultraviolet absorber that can absorb and block ultraviolet light may be used alone, an ultraviolet absorber that can absorb ultraviolet light and perform wavelength conversion of the ultraviolet light into light having longer wavelength than that of the ultraviolet light may be used alone, and an ultraviolet absorber that can absorb and block ultraviolet light and an ultraviolet absorber that can absorb ultraviolet light and perform wavelength conversion of the ultraviolet light into light having longer wavelength than that of the ultraviolet light may be used in combination.

As necessary, the ultraviolet absorbing layer may comprise a binder in order to hold the ultraviolet absorber. A preferred binder is a material that can hold the ultraviolet absorber in the ultraviolet absorbing layer without significantly impairing the effect of the present invention, and a resin is usually used. Examples of the resin usable as the binder may include a polyester resin, an epoxy resin, an acrylic resin, and a fluorine resin. The binders may be used alone or in combination of two or more of them at any ratio.

The binder is usually used in an amount of 3 parts by weight or more, preferably 5 parts by weight or more, and more preferably 10 parts by weight or more, and is usually used in an amount of 80 parts by weight or less, preferably 50 parts by weight or less, and more preferably 30 parts by weight or less, with respect to 100 parts by weight of the ultraviolet absorber. The ultraviolet absorbing layer using the binder in an excessively small amount may unstably hold the ultraviolet absorber, while the ultraviolet absorbing layer using the binder in an excessively large amount may insufficiently absorb the ultraviolet light.

The ultraviolet absorbing layer may contain other components in addition to the ultraviolet absorber and the binder as long as the effect of the present invention is not significantly impaired. Examples of the component may include additives such as a filler and an antioxidant.

The other components may be used alone or in combination of two or more of them at any ratio.

The ultraviolet absorbing layer usually has a thickness of 1 μm or larger, preferably 10 μm or larger, and more preferably 100 μm or larger, and usually has a thickness of 10,000 μm or smaller, preferably 5,000 μm or smaller, and more preferably 3,000 μm or smaller. The ultraviolet absorbing layer having an excessively small thickness may insufficiently absorb the ultraviolet light, while the ultraviolet absorbing layer having an excessively large thickness may excessively increase the thickness of the organic photovoltaic cell.

Examples of the method for forming the ultraviolet absorbing layer may include a gas phase film formation method, a coating method, and a method of bonding a previously formed film substance. Among them, the ultraviolet absorbing layer is preferably formed by the coating method because the layer can be readily formed to reduce the cost.

When the ultraviolet absorbing layer is formed by the coating method, a liquid composition comprising the ultraviolet absorber is firstly prepared, and a coating process of applying the prepared liquid composition onto a predetermined area is carried out to form the ultraviolet absorbing layer.

The liquid composition for forming the ultraviolet absorbing layer usually comprises a material for the ultraviolet absorbing layer, such as the ultraviolet absorber and the binder comprised as necessary, and a solvent. When the solvent is contained, the liquid composition may be a dispersion liquid dispersing the material for the ultraviolet absorbing layer in the solvent and may be a solution dissolving the material for the ultraviolet absorbing layer in the solvent.

Examples of the solvent contained in the liquid composition for forming the ultraviolet absorbing layer may include solvents similar to the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the wavelength absorber.

After the preparation of the liquid composition for forming the ultraviolet absorbing layer, the liquid composition is applied onto a predetermined area where the ultraviolet absorbing layer is intended to be formed. Usually, the liquid composition is applied so as to cover a surface of the resin layer. Examples of the coating method of the liquid composition may include coating methods similar to the coating methods of the liquid composition for forming the active layer.

The liquid composition for forming the ultraviolet absorbing layer is applied to form a film comprising the ultraviolet absorber. Thus, after the application of the liquid composition, as necessary, a process such as a process of drying the formed film to remove the solvent is performed, and consequently the ultraviolet absorbing layer is obtained.

[6-4. Other Items Relating to Barrier Layer]

The barrier layer may have other layers in addition to the inorganic sealing layer, the resin layer, and the ultraviolet absorbing layer as long as the effect of the present invention is not significantly impaired.

In the barrier layer, the inorganic sealing layer, the resin layer, and the ultraviolet absorbing layer are not required to be in contact with each other. Hence, for example, other layers may be provided between the inorganic sealing layer, the resin layer and the ultraviolet absorbing layer. However, the inorganic sealing layer, the resin layer, and the ultraviolet absorbing layer are preferably in contact with each other in order to remarkably exert the effect of the present invention.

In the barrier layer, one inorganic sealing layer, one resin layer, and one ultraviolet absorbing layer may be provided or two or more of the inorganic sealing layers, two or more of the resin layers, and two or more of the ultraviolet absorbing layers may be provided. Thus, for example, the resin layer may be further provided on an outside of the ultraviolet absorbing layer, the ultraviolet absorbing layer may be further provided on an inside of the inorganic sealing layer, and two or more of layers may be stacked to form the ultraviolet absorbing layer having a stacked structure layer.

### 7. Other Layer

The organic photovoltaic cell of the present invention may comprise other layers in addition to the substrate, the first electrode, the second electrode, the active layer, the barrier layer, and the functional layer as long as the effect of the present invention is not significantly impaired.

### 8. Embodiments

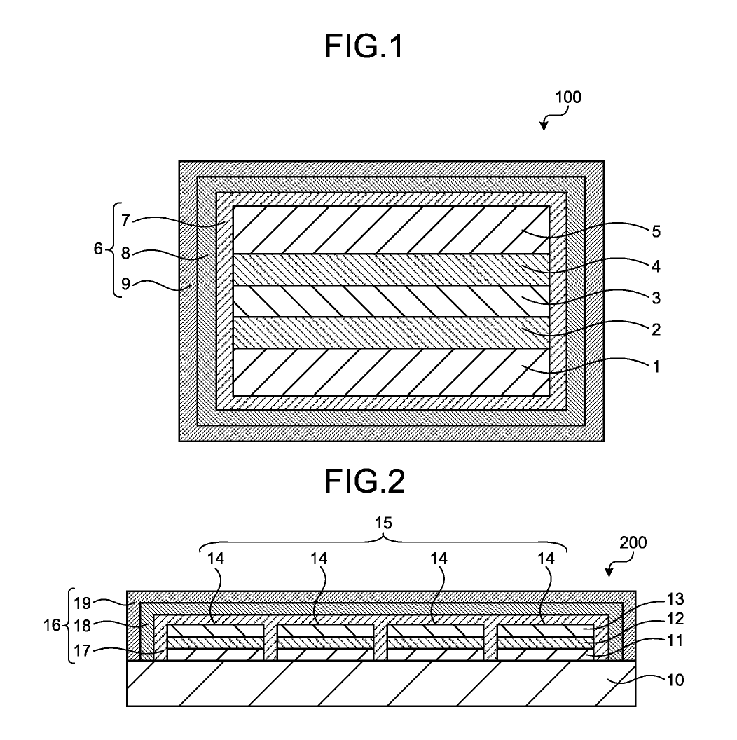

Hereinafter, preferred embodiments of the organic photovoltaic cell of the present invention will be described with reference to drawings. FIG. 1 is a schematic cross-sectional view of the organic photovoltaic cell of one embodiment of the present invention. In the below embodiments, the organic photovoltaic cell will be described while the substrate is placed horizontally.

An organic photovoltaic cell 100 illustrated in FIG. 1 comprises, on a substrate 1, a first electrode 2, an active layer 3 capable of generating a charge by incident light, a second electrode 4, and a substrate 5 in this order. Each of the first electrode 2 and the second electrode 4 is connected with a terminal not illustrated in the schematic for extracting electricity to the exterior. A surface of the organic photovoltaic cell 100 has a barrier layer 6 that is configured so as to be the whole surface of the organic photovoltaic cell 100. Thus, the organic photovoltaic cell 100 comprises the first electrode 2, the second electrode 4, the active layer 3 provided between the first electrode 2 and the second electrode 4, and the barrier layer 6 configured to be the surface of the organic photovoltaic cell 100.

The barrier layer 6 comprises an inorganic sealing layer 7 comprising an inorganic material, a resin layer 8 formed from a resin, and an ultraviolet absorbing layer 9 capable of absorbing ultraviolet light in this order from the active layer 3.

The organic photovoltaic cell 100 has the structure as described above. Hence, when light is applied, the applied light is input to the active layer 3 to generate charges in the active layer 3. The charges generated in the active layer 3 are transported to the first electrode 2 and the second electrode 4, and each is extracted through the terminal to the exterior.

The organic photovoltaic cell 100 comprises the barrier layer 6 comprising the inorganic sealing layer 7, the resin layer 8, and the ultraviolet absorbing layer 9 in this order from the active layer 3, and therefore can block the penetration of oxygen and water from outside to inside of the organic photovoltaic cell 100, can suppress the damage to the inorganic sealing layer 7 and the like caused by external force from outside of the organic photovoltaic cell 100 to the inorganic sealing layer 7 and the like, and can suppress the deterioration of the organic materials due to ultraviolet light included in light applied to the organic photovoltaic cell 100. The ultraviolet absorbing layer 9 that has the function of wavelength conversion of absorbed ultraviolet light into light having longer wavelength than that of the ultraviolet light can increase light energy that is input to the active layer 3 and that is available for the charge generation.

Therefore, the organic photovoltaic cell 100 of the present embodiment can be likely to suppress deteriorations of the first electrode 2, the active layer 3, and the second electrode 4 due to oxygen, water, and ultraviolet light and can increase the resistance to external force. On this account, the organic photovoltaic cell 100 is an organic photovoltaic cell that can maintain the photovoltaic conversion efficiency for a longer time than that of a conventional organic photovoltaic cell to elongate the lifetime. The ultraviolet absorbing layer 9 that has the function of wavelength conversion of absorbed ultraviolet light into light having longer wavelength than that of the ultraviolet light can increase the generation amount of charges in the active layer and therefore can improve the photovoltaic conversion efficiency.

### 9. Application of Organic Photovoltaic Cell

In the manner described above, photoelectromotive force is generated between the electrodes of the organic photovoltaic cell of the present invention by the irradiation of light such as sunlight. The organic photovoltaic cell of the present invention may be used, for example, as a solar cell using the photoelectromotive force. When the organic photovoltaic cell is used as the solar cell, the organic photovoltaic cell of the present invention is usually used as the solar cell for an organic thin film solar cell. The plurality of solar cells may also be integrated to make a solar cell module (organic thin film solar cell module) to be used as the solar cell module. The organic photovoltaic cell of the present invention has long lifetime as described above; therefore, a solar cell comprising the organic photovoltaic cell of the present invention can be expected to have longer lifetime.

The organic photovoltaic cell of the present invention may also be used as an organic optical sensor. For example, when the organic photovoltaic cell of the present invention is irradiated with light while applying electrical voltage between the electrodes or without the application, a charge is generated. Hence, when the charge is detected as a photocurrent, the organic photovoltaic cell of the present invention can serve as the organic optical sensor. The plurality of organic optical sensors may be integrated to be used as an organic image sensor.

### 10. Organic Photovoltaic Module

The organic photovoltaic module of the present invention comprises a cell group comprising two or more organic photovoltaic cells that are electrically connected to each other and a barrier layer covering the cell group. Each organic photovoltaic cell comprised in the cell group is the same as the organic photovoltaic cell of the present invention except that the cell does not necessarily include the barrier layer. The barrier layer included in the organic photovoltaic module of the present invention is the same as the barrier layer included in the organic photovoltaic cell of the present invention except that the barrier layer is not configured to be each surface of the organic photovoltaic cells individually but is provided so as to cover the cell group and that the barrier layer comprises the inorganic sealing layer, the resin layer, and the ultraviolet absorbing layer in this order from the organic photovoltaic cell. The organic photovoltaic cells comprised in the cell group may be electrically connected in series or in parallel. The organic photovoltaic module of the present invention having the structure as described above can obtain longer lifetime as with the effective photovoltaic cell of the present invention.

The organic photovoltaic module of the present invention may further comprise other components in addition to the cell group and the barrier layer as long as the effect of the present invention is not significantly impaired. Examples of the other component may include a supporting substrate for supporting the cell group, a sealer layer for sealing each organic photovoltaic cell, a wire for electrically connecting the organic photovoltaic cells to each other, and a terminal for extracting current from the organic photovoltaic module.

FIG. 2 illustrates an embodiment of the organic photovoltaic module of the present invention. FIG. 2 is a schematic cross-sectional view of an organic photovoltaic module of an embodiment of the present invention. In the below embodiment, the organic photovoltaic module will be described while a supporting substrate is placed horizontally.

An organic photovoltaic module 200 illustrated in FIG. 2 comprises, on a supporting substrate 10, two or more (four in FIG. 2) organic photovoltaic cells 14 that comprise a first electrode 11, an active layer 12, and a second electrode 13 in this order. The organic photovoltaic cells 14 are electrically connected to each other through wires not illustrated in the schematic. The two or more organic photovoltaic cell groups 14 are combined to form a cell group 15. The wire is connected to a terminal that is provided at a periphery of the organic photovoltaic cell 200 and that is not illustrated in the schematic, for extracting electricity to the exterior. In the organic photovoltaic module 200, a barrier layer 16 is provided so as to cover the whole surface of the cell group 15 except for a surface area with which the supporting substrate 10 is in contact. The barrier layer 16 comprises the inorganic sealing layer 17, the resin layer 18, and the ultraviolet absorbing layer 19 in this order from the organic photovoltaic cell 14.

The organic photovoltaic module 200 has the structure as described above. Hence, when light is applied, the applied light is input to the active layer 12, thus generating charges in the active layer 12. The charges generated in the active layer 12 are transported to the first electrode 11 and the second electrode 12 and extracted through each wire and each terminal to the exterior.

The organic photovoltaic cell 200 comprises the barrier layer 16. Thus, as with the description in the organic photovoltaic cell of the present invention, the organic photovoltaic cell 200 can be likely to suppress deteriorations of the first electrode 11, the active layer 12, and the second electrode 13 due to oxygen, water, and ultraviolet light and can increase the resistance to external force. On this account, the organic photovoltaic cell 200 is an organic photovoltaic module that can maintain the photovoltaic conversion efficiency for a longer time than that of a conventional organic photovoltaic module to elongate the lifetime. The ultraviolet absorbing layer 19 that has the function of wavelength conversion of absorbed ultraviolet light into light having longer wavelength than that of the ultraviolet light can also increase the generation amount of charges in the active layer 12 and therefore can improve the photovoltaic conversion efficiency.

### 11. Solar Cell Module

Hereinafter, an example of the configuration of a solar cell module as the organic photovoltaic module using the organic photovoltaic cell as a solar cell will be described.

The solar cell module may basically have the same module structure as that of a conventional solar cell module. The solar cell module generally comprises a supporting substrate, such as a metal and ceramics, on which a solar cell is provided. The solar cell is covered with a filling resin, a protection glass, and the like. Hence, the solar cell can take in light through the side opposite to the supporting substrate. The solar cell module may use a transparent material such as a tempered glass as the supporting substrate, on which the solar cell is provided for taking in light through the transparent supporting substrate.

Known examples of the structure of the solar cell module may include module structures such as a superstraight type, a substrate type, and a potting type; and a substrate-integrated module structure used in an amorphous silicon solar cell. A specific module structure may be appropriately selected as a suitable module structure depending on an intended purpose, place, environment, and the like.

For example, in the solar cell modules of the superstraight type and the substrate type as typical module structures, the solar cells are arranged at certain intervals between a pair of supporting substrates. One or both of the supporting substrates are transparent and are usually subjected to an anti-reflective treatment. The adjacent solar cells are electrically connected to each other through wiring such as a metal lead and a flexible wire, and an integrated electrode is placed at a periphery of the solar cell module for extracting electric power generated in the solar cell to the exterior.

Between the supporting substrate and the solar cell, a layer of a filler material such as a plastic material including ethylene vinyl acetate (EVA) may be provided as necessary in order to protect the solar cell and to improve the electric current collecting efficiency. The filler material may be previously formed into a film-shape for installing, or a resin may be filled at a desired position and then cured.

When the solar cell module is used at a place where a hard material is not needed for covering the surface, for example, at a place unlikely to suffer from impact from outside, one of the supporting substrate may not be provided. However, the surface without the supporting substrate of the solar cell module preferably has a surface protection layer by, for example, being covered with a transparent plastic film or being covered with a filler resin to be cured for imparting a protection function.

The periphery of the supporting substrate is usually fixed with a metal frame while interposing the solar cell module in order to seal the inside and to secure rigidity of the solar cell module. A space between the supporting substrate and the frame is usually sealed with a sealing material.

The solar cell module can be used while utilizing the advantages of the organic photovoltaic cell because the solar cell module comprises the organic photovoltaic cell that is a photovoltaic cell using an organic material. For example, the organic photovoltaic cell can be formed as a flexible cell, and thus when flexible materials are used for the supporting substrate, the filler material, the sealing material, and the like, a solar cell module can be provided on a curved surface.

The organic photovoltaic cell can be produced using a coating method at low cost, and hence the solar cell module can also be produced using the coating method. For example, when a solar cell module is produced using a flexible support such as a polymer film as the supporting substrate, a solar cell is sequentially formed using the coating method and the like while feeding the flexible support from a roll flexible support, the flexible support is cut into a desired size, and a peripheral part of the cut out piece is sealed with a flexible and moisture-proof material to produce a body of the solar cell module. For example, a solar cell module having a module structure so-called “SCAF” described in “Solar Energy Materials and Solar Cells, 48, p 383-391” can also be obtained.

The solar cell module using the flexible support may also be bonded and fixed to a curved surface glass and the like to be used.

The solar cell module preferably uses the organic solar cell of the present invention having a surface with the barrier layer as at least one of the solar cells or preferably comprises the barrier layer that covers the cell group comprising solar cells as the organic solar cells. This leads to a solar cell module that can obtain the above described effect of the present invention.

### EXAMPLES

Hereinafter, the present invention will be specifically described with reference to examples, but the present invention is not limited to the examples described below, and any changes and modifications may be made in the present invention without departing from the gist of the present invention.

[Evaluation Method]

In Example and Comparative Example described below, a square organic photovoltaic cell having a size of 2 mm×2 mm was produced. For the produced organic photovoltaic cell, using CEP-2000 spectral response measurement system manufactured by Bunkoukeiki Co., Ltd., DC voltage application with respect to the cell was swept at a constant rate of 20 mV/second to determine a short circuit current, an open end voltage, and a fill factor D (hereinafter, appropriately abbreviated as “FF”), and the determined short circuit current was multiplied by the determined open end voltage and by the determined fill factor to calculate the photovoltaic conversion efficiency.

The produced organic photovoltaic cell was irradiated with sunlight out of doors for 6 hours for an atmospheric exposure test. In the atmospheric exposure test, sunlight was input from the glass substrate side formed with an ITO film to the active layer. After the atmospheric exposure test, the photovoltaic conversion efficiency was determined, and the photovoltaic conversion efficiency determined after the atmospheric exposure test was divided by the photovoltaic conversion efficiency immediately after the production of the organic photovoltaic cell to calculate a photovoltaic conversion efficiency retention. The short circuit current after the atmospheric exposure test was divided by an area of the active layer to determine a short circuit current density after the atmospheric exposure test.

### Example 1

A glass substrate patterned with an ITO film having a film thickness of about 150 nm by a sputtering method as the electrode was prepared. The prepared glass substrate was washed with an organic solvent, an alkaline detergent, and ultrapure water, then dried, and subjected to ultraviolet light-ozone treatment (UV-O₃ treatment) with an UV-O₃ apparatus.

A suspension of poly(3,4-ethylenedioxythiophene)/poly(styrene sulfonate) (manufactured by H.C. Starck-V TECH Ltd., Bytron P TP AI 4083) was prepared and filtered with a filter having a pore size of 0.5 μm. The filtered suspension was applied onto a surface formed with the ITO film on the glass substrate by spin coating to form a film having a thickness of 70 nm. Then, the film was dried in the atmosphere on a hot plate at 200° C. for 10 minutes to form a functional layer.

Next, an ortho-dichlorobenzene solution comprising a macromolecular compound A being an alternating polymer that was obtained by copolymerization of the monomer represented by Formula (3) and the monomer represented by Formula (4) and that had the repeating unit represented by Formula (5) and [6,6]-phenyl-C₆₁-butyric acid methyl ester (hereinafter, appropriately abbreviated as “[6,6]-PCBM”) at a weight ratio of 1:3 was prepared. The macromolecular compound A was 1% by weight with respect to ortho-dichlorobenzene. Then, the solution was filtered with a filter having a pore size of 0.5 μm. The obtained filtrate was applied onto the functional layer by spin coating and then was dried in an N₂ atmosphere. Consequently, an active layer having a thickness of 100 nm was obtained. The macromolecular compound A had the weight-average molecular weight of 17,000 in terms of polystyrene and had the number-average molecular weight of 5,000 in terms of polystyrene. The macromolecular compound A had an optical absorption edge wavelength of 925 nm.

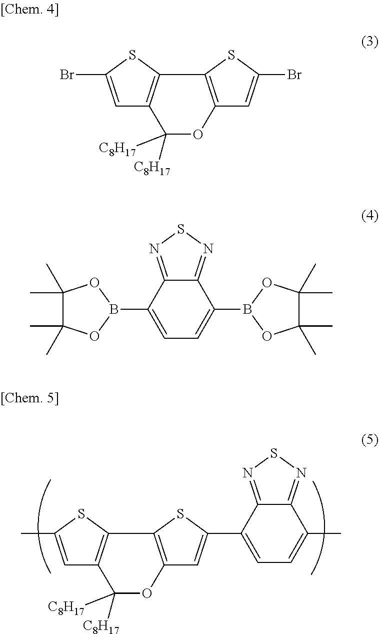

A dispersion liquid dispersing rutile type titanium dioxide particles (SCR-100C, Sakai Chemical Industry Co., Ltd.) in acetone was prepared. The dispersion liquid was applied onto the active layer by a spin coating method and dried at room temperature to form a functional layer having a thickness of 70 nm. The obtained functional layer was a layer also serving as the ultraviolet absorbing layer (UV cut layer) that was able to block light having a wavelength of 411 nm or smaller in the cell.

On the functional layer, a LiF film having a thickness of about 2.3 nm was formed in a resistance heating deposition apparatus to form a functional layer, and an Al film having a thickness of about 70 nm was subsequently formed to form an electrode.

Fourteen parts by weight of TiO₂ particles (manufactured by Sakai Chemical Industry Co., Ltd., trade name: SCR-100C) having an average particle diameter of about 10 nm and 6 parts by weight of an epoxy resin (manufactured by Robnor Resins, trade name: Robnor Adhesives (PX681C/HC)) were mixed into 80 parts by weight of ethanol to prepare a dispersion liquid. The prepared dispersion liquid was applied onto the Al film and dried to form an inorganic sealing layer having a thickness of 100 μm.

In order to improve denseness of the barrier layer, 10 parts by weight of titanium tetraisopoxide and 90 parts by weight of acetone were mixed to prepare a coating solution, and the solution was dropped onto the inorganic sealing layer. Consequently, on the inorganic sealing layer, the other inorganic sealing layer having a thickness of 20 μm was further formed.

Onto the inorganic sealing layer, an epoxy resin (manufactured by Nagase ChemteX Corporation, trade name: UV RESIN XNR 5516Z) as a photocurable resin was applied and cured by photoirradiation to form a resin layer having a thickness of 100 μm.

Onto the resin layer, a coating agent for blocking ultraviolet light (trade name: UV-G13) manufactured by Nippon Shokubai Co., Ltd. was applied to form an ultraviolet absorbing layer having a thickness of 6 μm.

In this manner, an organic photovoltaic cell comprising a barrier layer configured to be a surface of the organic photovoltaic cell was obtained. The barrier layer comprised two inorganic sealing layers, the resin layer, and the ultraviolet absorbing layer in this order from the active layer.

### Comparative Example 1

A glass substrate patterned with an ITO film having a film thickness of about 150 nm by a sputtering method as the electrode was prepared. The prepared glass substrate was washed with an organic solvent, an alkaline detergent, and ultrapure water, then dried, and subjected to UV-O₃ treatment with an UV-O₃ apparatus.

A suspension of poly(3,4-ethylenedioxythiophene)/poly(styrene sulfonate) (manufactured by H.C. Starck-V TECH Ltd., Bytron P TP AI 4083) was prepared and filtered with a filter having a pore size of 0.5 μm. The filtered suspension was applied onto a surface formed with the ITO film on the glass substrate by spin coating to form a film having a thickness of 70 nm. Then, the film was dried in the atmosphere on a hot plate at 200° C. for 10 minutes to form a functional layer.

Next, an ortho-dichlorobenzene solution comprising the macromolecular compound A and [6,6]-PCBM at a weight ratio of 1:3 was prepared. The macromolecular compound A was 1% by weight with respect to ortho-dichlorobenzene. Then, the solution was filtered with a filter having a pore size of 0.5 μm. The obtained filtrate was applied onto the functional layer by spin coating and then was dried in an N₂ atmosphere. Consequently, an active layer having a thickness of 100 nm was obtained.

On the active layer, a LiF film having a thickness of about 2.3 nm was formed in a resistance heating deposition apparatus to form a functional layer, and an Al film having a thickness of about 70 nm was subsequently formed to form an electrode.

Onto the Al electrode, a glass substrate was bonded with an epoxy resin (rapid setting type Araldite) as the sealer for sealing treatment to produce an organic photovoltaic cell.

Two organic photovoltaic cells were prepared and the prepared organic photovoltaic cells were collocated on an acrylic plate. The organic photovoltaic cell was placed so that the glass substrate close to the Al electrode would be in contact with the supporting substrate. Then, the organic photovoltaic cells were connected to each other in series through metal wires. Furthermore, from the organic photovoltaic cells placed at both ends, wires for extracting current were drawn out. Consequently, a module comprising the organic photovoltaic cells was produced.

After the production of the module, in a similar manner to that in Example 1, two inorganic sealing layers, the resin layer composed of the epoxy resin, and the ultraviolet absorbing layer composed of the coating agent for blocking ultraviolet light were formed so as to cover the whole of the cell group for the sealing with the barrier layer. During the formation of the inorganic sealing layers, the resin layer, and the ultraviolet absorbing layer, insufficiently coated areas were observed. Onto the insufficiently coated areas, the dispersion liquid, the coating solution, the resin, or the coating agent for blocking ultraviolet light used for forming each layer was applied by a dropping method or a dipping method so as to evenly cover the cell group with the barrier layer.

In this manner, an organic photovoltaic module comprising a barrier layer configured to be a surface of the organic photovoltaic module was obtained. The barrier layer comprised two inorganic sealing layers, the resin layer, and the ultraviolet absorbing layer in this order from the organic photovoltaic cell.

[Evaluation Result]

The organic photovoltaic cell produced according to Example was able to suppress the reduction of the photovoltaic conversion efficiency retention with time during the atmospheric exposure test as compared with a conventional organic photovoltaic cell. Namely, the organic photovoltaic cell of Example had long lifetime.

TABLE 1

| | | Comparative |
|---|---|---|
| | Example 1 | Example 1 |
| Photovoltaic Conversion | 80.97 | 76.21 |
| Efficiency Retention [%] | | |
| Short Circuit Current | 7.34 | 7.07 |
| Density after Atmospheric | | |
| Exposure Test [mA/cm²] | | |

### INDUSTRIAL APPLICABILITY

The organic photovoltaic cell of the present invention can be used as, for example, a solar cell and a photosensor.

1. An organic photovoltaic cell comprising:
a first electrode;
a second electrode; and
an active layer provided between the first electrode and the second electrode and capable of generating a charge by incident light, and
a barrier layer that is configured to be a surface of the organic photovoltaic cell, and that comprises an inorganic sealing layer comprising an inorganic material, a resin layer formed from a resin, and an ultraviolet absorbing layer in this order from the active layer.

2. The organic photovoltaic cell according to claim 1, wherein the ultraviolet absorbing layer has one or both of a function of blocking absorbed ultraviolet light and a function of wavelength conversion of absorbed ultraviolet light into light having longer wavelength than that of the ultraviolet light.

3. An organic photovoltaic module comprising:
a cell group comprising two or more organic photovoltaic cells that each comprises a first electrode, a second electrode, and an active layer provided between the first electrode and the second electrode and capable of generating a charge by incident light, and the two or more organic photovoltaic cells being electrically connected to each other; and
a barrier layer covering the cell group, wherein
the barrier layer comprises an inorganic sealing layer comprising an inorganic material, a resin layer formed from a resin, and an ultraviolet absorbing layer in this order from the organic photovoltaic cells.

4. The organic photovoltaic cell according to claim 1, wherein the inorganic sealing layer, the resin layer, and the ultraviolet absorbing layer are formed through a coating process.
